(19) United States
(12) Patent Application Publication
(10) Pub. No.: US 2026/0038585 A1
(43) Pub. Date: Feb. 5, 2026

(54) MEMORY POWER DIGITAL MULTIPLEXER

(71) Applicant: Arm Limited, Cambridge (GB)

(72) Inventors: Andy Wangkun Chen, Austin, TX (US); Yew Keong Chong, Austin, TX (US); Rahul Mathur, Austin, TX (US); Mohit Chanana, Noida (IN); Ankur Goel, Noida (IN)

(21) Appl. No.: 18/790,879

(22) Filed: Jul. 31, 2024

(51) Int. Cl. G11C 11/417; G11C 5/14

(52) U.S. Cl. CPC G11C 11/417; G11C 5/14

(57) ABSTRACT

A memory instance comprises a bitcell array and peripheral circuitry. A bitcell array power supply provides a fixed voltage for the bitcell array, and a peripheral logic power supply provides a variable voltage for peripheral circuitry. A digital power multiplexer is operable to provide a higher of the bitcell array power supply fixed voltage and the peripheral logic power supply variable voltage to the bitcell array.

### FIELD

The field relates generally to power management in a memory, and more specifically to digitally multiplexing power in a memory.

### BACKGROUND

Computers store information in a variety of ways, including magnetic disk storage that has high capacity and retains its data after power is no longer supplied, nonvolatile semiconductor memory such as flash memory that similarly retains its state when power is disconnected, and volatile memory such as Static Random Access Memory (SRAM) and Dynamic Random Access Memory (DRAM) that operate more quickly but that do not retain their data states when power is removed. SRAM uses semiconductor devices such as transistors to store data, while DRAM typically uses a small capacitor to store data state and must be “refreshed” or rewritten every few seconds or it may lose its data state. Although SRAM bitcell structures are typically larger than DRAM bitcell structures, they operate faster and are therefore preferred for applications such as cache and for internal registers of a CPU. Slower but cheaper DRAM is commonly used for a computer's main memory, where capacity is the primary concern.

SRAM typically comprises a bitcell array of memory cell or bitcell structures that are each operable to store a bit (e.g., a one or zero value) of information, along with peripheral circuitry such as address decoders and circuitry operable to write or erase the contents of bitcells in the bitcell array. In some examples, the bitcell memory cell structures may be addressable via peripheral circuitry as words, where each word comprises a number of bits such as eight bits, 16 bits, 32, bits, or 64 bits that represent a single unit of data that is handled by the processor. A typical modern processor may have a number of registers used during execution of program instructions to store instruction operands and results, each of which may be formed using SRAM or a similar memory structure.

Similarly, frequently-used data may be stored in a cache local to the processor, which may typically contain tens of thousands or hundreds of thousands (or more) of words of data per core in the processor. Local cache made of SRAM bitcell arrays makes retrieval of this often-used data faster than if the same data was retrieved from main memory (or DRAM), which is typically slower and not stored local to the processor. Because SRAM registers, cache, and the like may often be integrated onto the processor die along with processor cores, graphics processors, and the like, they may take up a significant percentage of the processor die area, transistor count, and power consumed by the integrated device. But, when modern processors are operated at different performance levels and different associated voltages, such as being driven voltages that may span a range where overdriven voltages are more than two times underdriven voltages, powering the cache memory and associated peripheral circuitry and processor cores may become complex. Some modern processor designs may have seven or more different performance levels and associated different drive voltages, making routing and switching available power supplies to each processor core and associated cache memory a difficult challenge.

Some computing systems therefore seek to switch or multiplex power to the various processor cores and associated caches in the computing system, but face challenges such as how to route multiple voltages to processor cores and associated cache memory, how to handle differing minimum voltage requirements of cache memory and processor cores, and how to perform reverse level shifting when the processor cores are at a higher voltage than cache memory without creating a DC path between different supply voltages. For reasons such as these, a need exists for improved power management in memory arrays.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a block diagram of a multi-core computing system having digitally multiplexed memory power, consistent with an example embodiment.

FIG. 2 is a block diagram of a processor cache memory, consistent with an example embodiment.

FIG. 3 shows an example digital power multiplexer circuit, consistent with an example embodiment.

FIG. 4 shows an example digital power multiplexer circuit having diode clamps, consistent with an example embodiment.

FIG. 5 shows a circuit diagram of a digital power multiplexer circuit including a power down state, consistent with an example embodiment.

FIG. 6 is a flow diagram of a method of digitally multiplexing power signals for a cache memory, consistent with an example embodiment.

FIG. 7 is a schematic diagram of a static random access memory (SRAM) cell, consistent with an example embodiment.

FIG. 8 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Data storage in computerized systems typically includes nonvolatile storage such as magnetic disk storage or flash memory that retains data such as an operating system, installed programs, saved files, and the like when a computer is powered off as well as volatile memory that loses its contents when power is removed. Volatile memory is typically much faster at reading and writing data, and so is used to hold certain operating system components, executing programs, and other data being actively used while a computer is powered on.

Modern computing systems may also employ multiple processor cores or multiple types of processor cores, including processor cores that may be operable at different performance levels. These different performance levels may involve operating the processor cores and their associated cache memories (e.g., level one and level two caches local to each respective processor core) at different voltages, such that low voltage operation may provide slower performance but may conserve power relative to higher voltage operation. On battery-powered devices such as smartphones, tablet computers, and the like, it may be desirable to provide such savings in battery life when performing low power operations such as reading a web page while providing for high performance operation during activities such as mobile gaming. But, challenges exist with respect to how to provide different voltage power supply signals to the processor cores and associated cache memories, especially when different cores may operate at different voltages or different performance levels.

The power supply voltages provided to processor cores and associated caches in some examples may vary significantly depending on the operating mode of the processor, such as ranging from 0.55V to 1.15 v in 0.1V increments in one example. Each of these increments may represent a different normal, underdriven, or overdriven operating state of the processor, and may be associated with a different voltage that a power supply may deliver to the processor and/or the associated cache memory. As the number of different voltage levels increases, routing the different power signals to different processor cores and cache memories becomes increasingly complex. Cache memory may further require a certain minimum voltage higher than a minimum voltage available to the processor cores in some performance modes, resulting in split voltage rails between the processor cores and associated cache memories.

Switching or multiplexing available supply voltages to the processor cores and associated cache memories may introduce several potential problems, including how to route a large number of different voltage supplies to each of the processors and cache memories, how to handle different minimum voltage requirements between the cache memories and processors, and how to perform reverse level shifting when the processor cores are at a higher voltage than cache memory without creating a DC path between different supply voltages.

Some example embodiments presented herein address challenges such as these in various methods or devices by providing various power signal multiplexing functions to the processors and associated caches depending on their operating mode. In one such example, a cache memory comprising a bitcell array and peripheral circuitry is connected to a bitcell array power supply providing a fixed voltage. The fixed voltage may be a minimum acceptable operating voltage for the bitcell array in a further example (such as 0.75 v), which may be higher than a minimum operating voltage for peripheral circuitry and/or an associated processor (such as 0.55 v). A peripheral logic power supply may provide a variable voltage to the peripheral circuitry, and a multiplexer may provide a higher of the bitcell array power supply fixed voltage and the peripheral logic power supply variable voltage to the bitcell array. In a more detailed example, providing the higher of the bitcell array power supply fixed voltage and the peripheral logic power supply variable voltage to the bitcell array may ensure that the bitcell array operates at or above its minimum voltage requirement while preventing reverse level shifting in which the peripheral circuitry is at a higher voltage than the bitcell array.

In another example, a power multiplexer includes an overdrive input operable to receive an indication of whether a first power voltage is higher than a second power voltage, where the overdrive input signal is driven at the second power voltage. A first switch may be coupled to receive the first power voltage and the overdrive input, such that the first switch is configured to selectively provide the first power voltage to an output based at least in part on the overdrive input. A level shifter may be operable to receive the overdrive input and to provide an inverted level-shifted overdrive input driven at the first power voltage. A second switch may be coupled to receive the second power voltage and the inverted level-shifted overdrive input, the second switch configured to selectively provide the second power voltage to the output based at least in part on inverted level-shifted overdrive input. In a more detailed example, the first and second switches comprise transistors such as field-effect transistors. In a further example, the power multiplexer is configured to avoid a direct current path between the first input voltage and the second input voltage

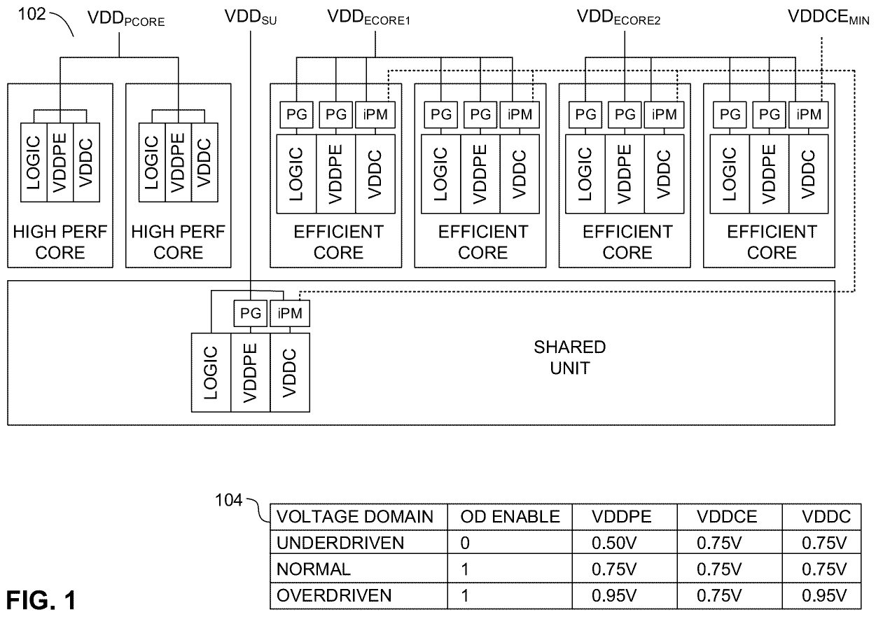

FIG. 1 is a block diagram of a multi-core computing system having digitally multiplexed memory power, consistent with an example embodiment. The computing system shown generally at 102 comprises two high-performance processor cores on the left side of the drawing, four efficient processor cores on the right side of the drawing, and a shared unit shown below the processor cores. The high performance processor cores in this example are powered by a performance core power signal, denoted “VDD_{PCORE}.” Two of the efficient processor cores are powered by a first efficient core power signal denoted “VDD_{ECORE1},” and two of the efficient processor cores are powered by a second efficient processor power signal denoted “VDD_{ECORE2}.” In a further example, one or more of the processor core voltages, such as “VDD_{ECORE1}” and/or “VDD_{ECORE2}.” may be variable such that the power signal provided varies in voltage depending on a desired operating state or voltage domain of the associated processor cores. An additional cache memory power signal denoted “VDDCE_{MIN}” provides a desired operating voltage to operate cache memory associated with the efficient cores, which in a further example may not vary from a selected operating voltage such as a determined safe minimum operating voltage.

The shared unit (pictured below the processor cores in FIG. 1) in some examples comprises additional cache, such as a level three or L3 cache, system control registers, power state control circuitry, clock gating control, debug circuitry, and/or other circuitry supporting the operation of the six processor cores pictured above, and may be coupled to each of the high performance processor cores and efficient processor cores. The shared unit in the example of FIG. 1 shows additional logic circuitry powered by its own VDD_{SU} power supply signal, as well as a level three or L3 cache comprising one or more bitcell arrays powered by VDDC (derived from VDDCE_{MIN}) and cache peripheral or control circuitry powered by VDDPE (derived from VDD_{SU}).

In operation, demanding tasks such as video playback or rendering games may be performed using the high performance cores (either with or without the aid of other processor cores), while less demanding tasks such as checking email or using a web browser may be performed using the efficient cores. The two efficient cores in the example of FIG. 1 located to the right of the drawing may further be operated in different performance modes or voltage domains, such as operating at a normal voltage for normal operations, operating at an underdriven voltage for a low performance but energy efficient mode, or operating at an overdriven voltage for a high performance mode that consumes more power than underdriven or normal voltage modes. In further examples, the operating frequency or other such characteristics of the efficient core processors may change along with the voltage, such as operating at a higher clock frequency when in an overdriven voltage mode or operating at a lower clock frequency when in an underdriven voltage mode.

The example of FIG. 1 provides separate power supply voltages for logic circuits (denoted “LOGIC” for processor logic and “VDDPE” for cache memory peripheral circuitry) and for cache bitcell arrays (denoted VDDC). This ensures in some examples that the cache bitcell arrays are always powered using at least a minimum desired voltage, such as a minimum safe operating voltage for the bitcell arrays, while allowing logic circuitry to operate at underdriven voltages lower than the cache bitcell array operating voltage. An integrated digital power multiplexer (denoted iPM in the efficient processor cores of FIG. 1) is connected to both the VDDCE_{MIN} bitcell array power signal and an associated one of the VDD_{ECORE1} and VDD_{ECORE2} variable efficient processor power signals, and in a further example is operable to select between the higher of the two voltage signals and provide that higher voltage power signal to power the bitcell arrays. In this example, the bitcell array will not be powered by a lower voltage than the VDDCE_{MIN} bitcell array power signal even when a coupled VDD_{ECORE1} Or VDD_{ECORE2} variable efficient processor power signal is underdriven at a lower voltage than the VDDCE_{MIN} bitcell array power signal, but will be driven at the associated VDD_{ECORE1} Or VDD_{ECORE2} voltage when the VDD_{ECORE1} Or VDD_{ECORE2} voltage exceeds VDDCE_{MIN}. The multiplexer in this example switches between voltage sources digitally, such as by using FET or other switching devices to switch between voltage supplied to the bitcell array associated with the efficient cores having digitally multiplexed cache memory power.

In a further example the shared unit also has an integrated digital power multiplexer (denote iPM), which is operable to provide a bitcell array power signal VDDC by selectively multiplexing between VDD_{SU} or the VDDCE_{MIN} bitcell array power signal. In a more detailed example, the digital power multiplexer again determines which of the VDD_{SU} or the VDDCE_{MIN} power signals is at a higher voltage level, and provides that power signal to the one or more bitcell arrays comprising the level three or L3 cache.

Operation of the integrated digital power multiplexer iPM supplying power to bitcell arrays associated with specific processor cores of FIG. 1 is further shown in table 104, which illustrates a simplified example having three different performance modes or voltage domains. In the “normal” voltage domain, the VDDPE voltage provided to the core's logic circuitry and peripheral cache circuitry is at 0.75V, as is the VDDCE voltage provided to the cache memory. The VDDCE cache memory power signal in this example is fixed, and represents a minimum safe operating voltage for the cache memory to operate reliably. The VDDPE voltage signal provided to the efficient core's logic circuitry and peripheral cache circuitry varies with different voltage domains, from 0.5V in the underdriven voltage domain to 0.95V in the overdriven voltage domain. An overdrive enable signal “OD Enable” is in a high state if the VDDPE voltage signal is higher than the VDDCE voltage signal, and a zero if the VDDPE voltage signal is lower than the VDDPE voltage signal. Its state may in various examples be either a zero or one if the VDDPE and VDDCE voltage signals are equal, as in the “normal” case. In a more detailed example, the OD Enable signal may be determined such as by using a comparator to determine whether the VDDPE voltage signal is higher than the VDDCE voltage signal.

Table 104 further illustrates that the bitcell array voltage VDDC may be overdriven with the VDDPE voltage if VDDPE exceeds the VDDCE voltage, to prevent a reverse voltage level shifting issue between the cache peripheral circuitry and the bitcell array and to eliminate a DC path between the higher VDDPE-powered peripheral circuitry and the lower VDDCE-powered bitcell arrays. In further examples with different overdriven voltage domains and corresponding VDDPE voltages, VDDC would be multiplexed to use the corresponding VDDPE voltage for power instead of VDDCE via the integrated power multiplexer iPM. Because the same VDDCE_{MIN} bitcell array power signal is distributed to every efficient core cache memory and a single VDD_{ECORE2} variable voltage is provided to each of the efficient cores having configurable voltage domains, the number of power domains in the example of FIG. 1 relative to traditional power distribution plans may be significantly reduced.

As the example of FIG. 1 shows, different processor cores or groups of processor cores may be coupled to different variable voltage power signals, such as VDD_{ECORE1} or VDD_{ECORE2} voltage signals, such that one processor or group of processors may operate in one voltage domain or performance mode while other processors or groups of processors operate in different voltage domains or performance modes. Although the example of FIG. 1 shows two processor groups of efficient core processors comprising two processor cores per group, greater or lesser numbers of processor groups and/or processors per group may be employed in other examples. By employing digital power multiplexing for bitcell arrays associated with processor cores connected to such voltage domains as shown in this example, a single bitcell voltage supply VDDCE_{MIN} may be utilized with one or more different logic and peripheral circuitry voltage domains such as VDD_{ECORE1} Or VDD_{ECORE2} to provide an improved power distribution network that avoids reverse level shifting in the bitcell memory arrays and that avoids creating a direct current path between different core logic and bitcell array operating voltages.

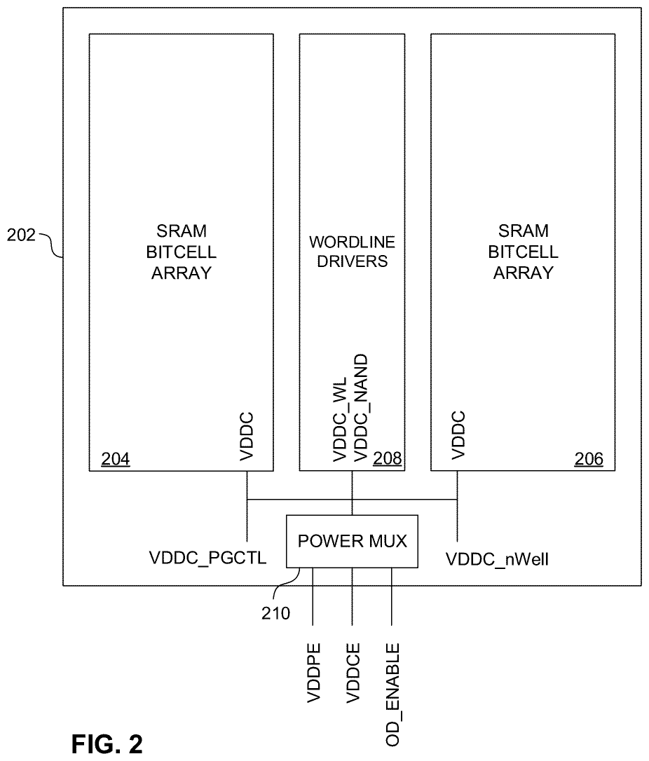

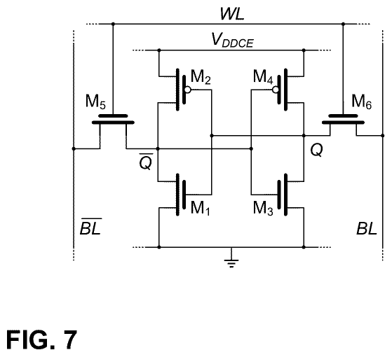

FIG. 2 is a block diagram of a processor cache memory, consistent with an example embodiment. The cache memory shown generally at 202 comprises one or more bitcell arrays 24 and 206, each of which comprises a grid of static random access memory (SRAM) bitcells operable to store a bit or binary digit of data. The bitcell arrays are accessed via bitlines and wordlines spanning the bitcell arrays in different dimensions, enabling random access for reading and writing data to the bitcells in the array. Wordline drivers 208 comprise a part of or interface with peripheral circuitry of the cache memory, and are operable to drive select wordlines in the bitcell arrays high to selectively read or write cache memory locations in the bitcell arrays. A more detailed description of bitcell, wordline, and bitline operation is provided in FIG. 7 and its accompanying description.

The cache memory in this example receives input power signals including VDDPE, VDDCE, and OD_ENABLE, and uses an integrated digital power multiplexer shown as Power MUX 210 to switch between providing VDDPE and VDDCE to the bitcell arrays and associated circuitry in response to the OD_ENABLE signal. In a more detailed example, the bitcell arrays and associated circuitry in the cache memory are operated using VDDCE when VDDCE is lower than VDDPE, and are operated using VDDPE when VDDPE is higher than VDDCE. When VDDCE and VDDPE are at the same voltage level, either VDDPE or VDDCE may be used to operate the cache memory, although VDDPE may be preferred in some embodiments to reduce the chances of a DC path between minor offsets between VDDPE and VDDCE.

The power MUX supplies the selected voltage signal to the SRAM bitcell arrays as VDDC, or the voltage used to power the individual bitcells in the arrays. The selected voltage is also used to power the n-wells of the semiconductor process used to construct the cache memory, as well as worldlines and NAND logic in the worldline drivers, PGCNTL, and other powered circuitry within the memory instance. In some examples, the power signal VDDC supplied to the bitcell arrays may be distributed such as via a bitcell supply header or other mechanism to ensure that adequate current is available across the cache memory.

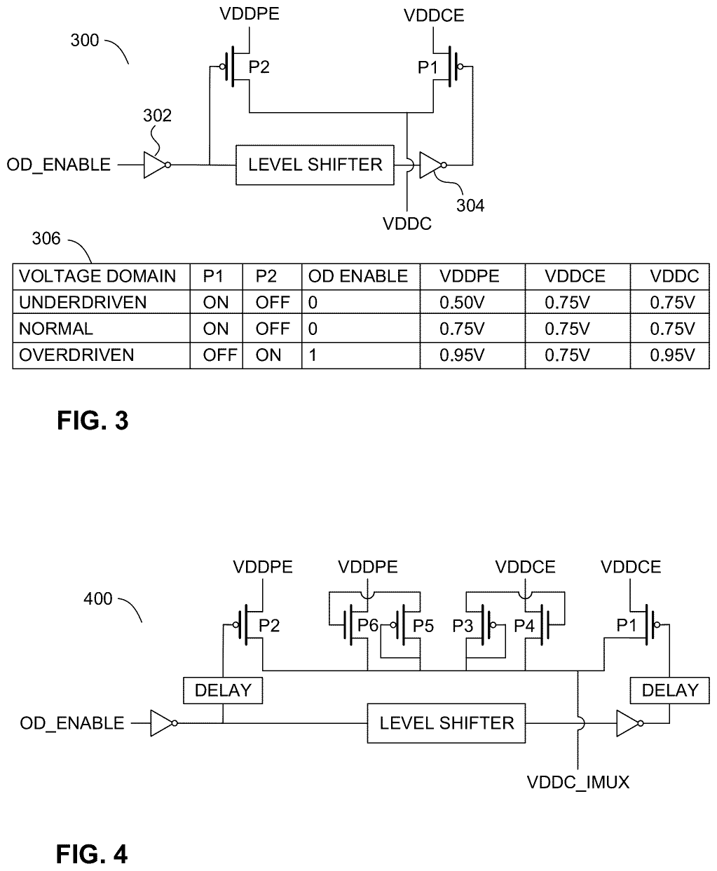

FIG. 3 shows an example digital power multiplexer circuit, consistent with an example embodiment. Here, an overdrive enable signal (denoted OD_ENABLE) is provided as an input to inverter 302, level shifter, and inverter 304. The outputs of the respective inverters are coupled to PMOS transistors, which selectively switch VDDPE or VDDCE to supply the bitcell arrays using power signal VDDC.

In a more detailed example, the output of inverter 302 is connected to the gate of PMOS transistor P2, which selectively provides the power signal VDDPE coupled to its drain to the VDDC bitcell array power input via its source based on the state of the inverted OD_ENABLE signal at the gate. The output of inverter 304 is similarly coupled to the gate of PMOS transistor P1, which selectively switches the power signal VDDCE connected to its drain to the VDDC bitcell array power input connected to its source.

The level shifter coupling inverter 302 and inverter 304 serves to shift the logic signal level from inverter 302's signal level, which is driven by VDDCE, to inverter 304's level, which is driven by VDDPE. In a more detailed example, the inverter 302 is powered via the VDDCE power signal and inverter 304 is powered by the VDDPE power signal, such that the larger of the two power signals VDDPE and VDDCE drives the PMOS gate that switches the corresponding PMOS transistor on, helping ensure that the other PMOS transistor doesn't conduct at the same time.

The chart shown at 306 of FIG. 3 illustrates how the OD_ENABLE signal representing the current voltage domain results in various power states of the digital multiplexer. When the OD_ENABLE signal indicates the voltage domain is underdriven or normal, transistor P2 receives a high signal at its inverting gate and does not conduct (or is switched off). PMOS transistor P1's gate is similarly provided a low signal by the output of inverter 304, and conducts or is in an “on” state due to effective inversion of the gate signal in PMOS devices. When the OD_ENABLE signal switches to a high signal value representing an overdriven voltage domain, the output of inverter 302 is low and PMOS transistor P2 is switched to an on state, conducting the VDDPE power signal across its drain and source to provide the VDDPE power signal as output VDDC. The signal provided to the gate of PMOS transistor P1 is switched high when the signal provided to the gate of PMOS transistor P2 is low due to inverter 304, and disconnects VDDCE from providing power to the output VDDC. The circuit of FIG. 3 therefore provides the VDDPE power signal as output VDDC when OD_ENABLE is high, and provides VDDCE power signal as output VDDC when OD_ENABLE is low.

FIG. 4 shows an example digital power multiplexer circuit having diode clamps, consistent with an example embodiment. The circuit shown in FIG. 4 is substantially similar in operation to the circuit of FIG. 3, except that diode clamps comprising transistors P3-P4 and P5-P6 are added between the input power signals VDDPE and VDDCE and the output power signal VNWPC, and delays are coupled to the inputs of each of PMOS transistors P1 and P2. The delay circuits in a more detailed example comprise NAND-based pulse shapers to slow input changes to PMOS transistors PI and P2 as OD_ENABLE changes state, further ensuring that the voltage supplies VDDPE and VDDCE are not inadvertently shorted together during power on.

The diode clamps comprising transistors P3-P4 and P5-P6 are in some examples configured to have a lower threshold voltage (Vₜ) than transistors P1 and P2, enabling them to change state faster. This facilitates the diode clamps protecting memory N wells from forward biasing or latchup due to an incorrect OD_ENABLE state on startup or ramp-up of initial signal levels. Both PMOS and NMOS clamps are provided here for process independence.

In a further example, the inverter coupled to receive OD_ENABLE may be replaced with a NAND gate having OD_ENABLE and VDDPE as inputs to protect from starting in an incorrect state during powerup, such as before a valid OD_ENABLE signal is received.

In some examples, the VNWPC signal is provided to N wells of bitcell arrays and peripheral circuitry of a memory such as the cache memory shown in FIG. 2, and is always in an “on” state providing the higher of VDDPE or VDDCE when the memory is powered on.

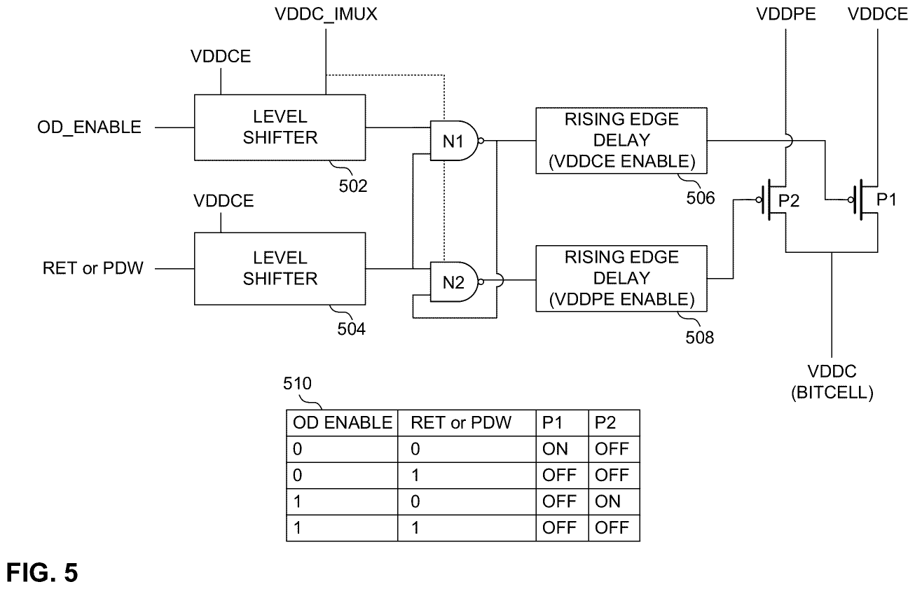

FIG. 5 shows a circuit diagram of a digital power multiplexer circuit including a power down state, consistent with an example embodiment. An input OD_ENABLE signal again provides an indication of whether a processor core associated with a cache memory is operating at an overdriven voltage domain or in an underdriven or normal voltage domain. If the OD_ENABLE signal indicates an overdriven voltage domain with a high signal level, the level shifter 502 feeds NAND gate N1 with the OD_ENABLE state along with a power down signal (PDW) that is level-shifted via level shifter 504. In alternate embodiments, the power down signal may be replaced with a retention mode power signal (RET), or another such signal indicating a temporarily powered down state. The output from NAND gate N1 is fed to a second NAND gate N2, along with the PDW or RET signal. The N1 NAND gate output is provided to a rising edge delay circuit 506 that in turn is coupled to the gate of PMOS transistor P1, which is operable to switch the VDDCE voltage supply signal from being coupled to the VDDC bitcell array power signal output. The output from NAND gate N2 is similarly provided to a rising edge delay circuit 508 that in turn is coupled to the gate of PMOS transistor P2, which is operable to switch the VDDPE voltage supply signal from being coupled to the VDDC bitcell array power signal output. In a further example, the larger of the two power supplies VDDCE and VDDPE may be used to power the logic gates of FIG. 5, such as the level shifters 502 and 504, the NAND gates N1 and N2, and the rising edge delay circuits 506 and 508.

In operation, when the OD_ENABLE signal goes high, the output of the N1 NAND gate goes high unless the RET or PDW signal is also high. The inputs of the N2 NAND gate are coupled to the output of the N1 NAND gate and the RET or PDW signal, so the output of the N2 NAND gate is high unless both the N1 NAND gate output and the RED or PDW signals are high. The output of NAND gate N1 is coupled via a rising edge delay circuit 506 to the gate of PMOS transistor P1 which selectively couples the VDDCE voltage supply to the VDDC bitcell voltage output, and the output of NAND gate N2 is similarly coupled via a rising edge delay circuit 508 to the gate of PMOS transistor P1, which selectively couples the VDDPE voltage supply to the VDDC bitcell voltage output.

The RET or PDW input can therefore ensure that the NAND gate outputs supplied to both the P1 and P2 PMOS transistors is high, shutting off both VDDPE and VDDCE from being supplied to the VDDC bitcell array output. When RET or PDW is low, the OD_ENABLE state selects whether the VDDCE or VDDPE voltage supply signals are coupled to the VDDC bitcell voltage output, as reflected in the Table shown at 510. The circuit of FIG. 5 is therefore operable to selectively power the bitcell array voltage supply up or down dependent on the RET or PDW signal, while selecting between VDDPE and VDDCE when in a powered up state. The VDDC output signal of FIG. 5 is in some examples derived from a VDDC_IMUX signal that is electrically isolated from the VNWPC signal to supply N well biasing such as is shown in FIG. 4 to avoid an inrush current path VNWPC during initial power on, despite VNWPC and VDDC_IMUX being derived from the same signals. In a further example, VDDC_IMUX is provided via a circuit such as that of FIG. 4, and is selectively used to drive transistors P1 and P2 such that these transistors are driven with the larger of VDDCE and VDDPE, ensuring that both can be turned off such as when OD_ENABLE and RET or PDW are both low.

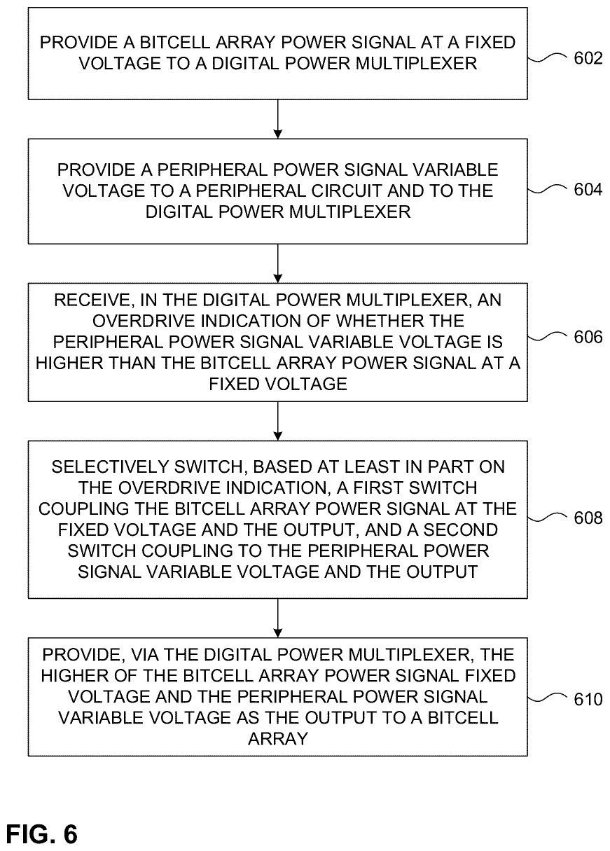

FIG. 6 is a flow diagram of a method of digitally multiplexing power signals for a cache memory, consistent with an example embodiment. At 602, a bitcell array power signal is provided to a bitcell array, which may be at a minimum reliable or acceptable operating voltage for the bitcells in the array. In one such example this may be 0.75V, but in other examples it may be a different value based on factors such as the semiconductor process, bitcell structure or design, and the like. A peripheral power signal having a variable voltage is also provided at 604, which in various embodiments may include normal operating voltage, underdriven modes such as voltages less than the normal operating voltage, or overdriven modes such as voltages higher than the normal operating voltage. Reducing voltage when possible may allow a processor to operate with lower power consumption and reduce the thermal cooling needed, while increasing voltage may allow higher operating frequencies and higher performance in some embodiments.

At 606, a digital power multiplexer receives an overdrive indication of whether the peripheral power signal's variable voltage is higher than the bitcell array power signal's fixed voltage. This may be determined in a more detailed example by a circuit such as a comparator, or by receiving a signal from a control circuit operable to adjust the operating mode and/or the voltage of the peripheral power signal. The overdrive indication is used at 608 to selectively switch a first switch coupled to the bitcell array power signal at the fixed voltage between being connected and disconnected to the output, and to further selectively switch a second switch coupled to the peripheral power signal variable voltage between being disconnected and connected to the output. The output is connected to only one of the bitcell array power signal at the fixed voltage and the peripheral power signal variable voltage at a time, and is connected to the peripheral power signal variable voltage when the peripheral power signal variable voltage exceeds the bitcell array power signal fixed voltage and to the bitcell array power signal fixed voltage when the bitcell array power signal fixed voltage exceeds the peripheral power signal variable voltage. When the two voltages are equal, the overdrive signal may be configured to take either state and either corresponding selected voltage supply may be coupled to the output.

The output is provided at 610 to the bitcell array of the memory, such as a level one (L1) or level two (L2) cache bitcell arrays. In a more detailed example, this results in the higher of the peripheral power signal variable voltage (VDDPE) and the bitcell array power signal fixed voltage (VDDCE) being provided to the bitcell arrays as the internal operating voltage (VDDC). In an alternate embodiment, the bitcell array power signal voltage VDDCE may vary between different voltage level or performance modes, such as between conservative and aggressive minimum operating voltage dependent on factors such as the semiconductor process, observed reliability and/or error rate, and the like.

Although the example of FIG. 6 discusses the voltage provided to the cache memory of a single processor, other examples may include providing the same voltages or performing the same functions in cache memories associated with other processors operating at the same voltage or having the same performance mode. In further examples, different groups of processors may operate at different voltages, such as having different peripheral power signal variable voltages VDDPE or performance modes for different groups of processors performing different tasks in a computing system.

Some examples presented here involve powering cache memory associated with a specific processor core, such as level one (L1) or level two (L2) cache memory. Cache memory is often comprised of Static Random Access Memory (SRAM) rather than Dynamic Random Access Memory (DRAM), which may impart an access latency higher than that of SRAM, but takes fewer components to build per memory cell. DRAM may store a memory state in a capacitive structure to be refreshed on the order of every few seconds to maintain its contents. SRAM may use a larger structure comprising several transistors such as Metal Oxide Semiconductor Field Effect Transistors (MOSFETs) to store data, but may operate with a lower access latency than that of DRAM and so may be preferred for applications where execution speed is more important than capacity such as in cache memory or processor registers.

Memory such as SRAM or DRAM may be built from semiconductors such as on an integrated circuit substrate as an array of bitcells that can each store a single bit of information (typically represented by a one or a zero state). Bitcells may be addressable for reading or writing via peripheral circuitry that accesses the desired bitcells using a combination of bitlines and wordlines, and includes the ability to read from and/or write to addressed bitcells. Bitcells are often addressed by words rather than by individual bitcell addresses, where each word comprises a number of bits (typically a power of two ranging from eight to 64) that make up a base unit of data handled by the processor. A modern 64-bit processor may therefore primarily work with 64-bit words (or may address bitcells 64 bits at a time), but in various examples may also perform single-bit operations or work with other word sizes as well for certain operations. A processor may also have multiple registers for use during execution of software instructions to hold data such as the operands and results being used for each instruction, typically on the order of tens of registers per processor core.

While a relatively slower DRAM may be desirable for main memory of a computer where capacity may be a greater concern than access latency, SRAM may be more applicable for use in processor registers and for cache memory located near the processor core (and often on the same die or substrate as the processor cores) where access latency is of greater concern. Cache memory may store data that is also stored in main memory, but because cache may comprise lower latency SRAM bitcells and may be small in size relative to main memory, cache may provide for faster processor access to data the processor is likely to use soon. A computing device may have multiple levels of cache (e.g., L1, L2, L3, etc.), because smaller caches have lower latency or higher speed but are less likely to contain the desired data than a larger cache. While SRAM may be used for cache memory, some processors, Multi-Chip Modules (MCMs), or Application-Specific Integrated Circuits (ASICs) may also use eDRAM, which is DRAM integrated on the same die or MCM as the processor or ASIC.

FIG. 7 is a schematic diagram of a static random access memory (SRAM) cell, consistent with an example embodiment. The SRAM memory cell of FIG. 7 is often referred to as a 6T SRAM cell due to its six transistors, but other SRAM memory cell configurations exist and may also be used to form bitcell arrays such as those in the examples presented herein.

The memory cell can store a “bit” or single high or low state of information using the four transistors M1, M2, M3, and M4. These four transistors form two cross-coupled inverters, which are stable in either a high or low (i.e., a 1 or 0) state. Access transistors M5 and M6 control access to the cross-coupled inverters formed by M1, M2, M3, and M4 during read and write operations. Word lines denoted by WL and bitlines denoted by BL are used to select which memory bitcells in a bitcell array are being addressed, and use of both a bitline BL and inverse bitline B̅L̅ may improve noise margins and speed of the SRAM bitcell.

In operation, the bitcell may operate in standby, reading, or writing states. In a standby state, the word line WL is not active, the access transistors M5 and M6 disconnect the cell from the bit lines, and the cross-coupled inverters formed by M1, M2, M3, and M4 reinforce each other to retain their state as long as they remain powered.

In a reading state, the word line WL is brought high, and one or both of the bitline BL and inverse bitline B̅L̅ may be read to determine the state of the bitcell. Because the bitlines are often relatively long and have some parasitic capacitance, reading the state of a memory cell is often done by precharging both bitlines BL and B̅L̅ with a one or high value, asserting the word line WL thereby enabling transistors M5 and M6, and observing which bitline voltage drops relative to the other bitline such as by using a comparator or sense amplifier to speed up the read operation.

To write a value to the bitcell the value to be applied is written to the bit lines, such as writing a one value as bringing bitline BL to a one or high state and B̅L̅ to a zero or low state. The word line WL is then asserted, and the value to be stored is latched into the bitcell. In a more detailed example, the bit line inputs are driven with a strong enough voltage signal to overcome the relatively weak transistors in the bitcell such that they can easily override the previous state of the bitcell's cross-coupled inverters. Because the inverters are cross-coupled, a slight change in state to one of the inverters (e.g. transistor pair M1 and M2) will help overwrite the state of the other pair of inverters. Access NMOS transistors M5 and M6 may be further designed to be stronger than the transistors M1, M2, M3, and M4, contributing to the speed of the write process.

Arrays of SRAM may be formed in a two-dimensional grid, with row and column decoders in peripheral circuitry selecting wordlines and bitlines associated with bitcells based on their memory address to access the bitcells. Bitcells are often accessed one word at a time, where a word may comprise a byte (or 8 bits), or another power of two such as 16, 32, or 64 bits. In other examples, memory operations may be conducted on words, single bits, pages of words, or other units of addressable memory to write and store information in the SRAM.

The examples shown here demonstrate how inrush current in a memory such as SRAM cache may be managed by using one or more integrated delay elements such as inverters, RC delay lines, and the like to significantly slow down power down signal propagation between memory instances in a memory array. The delay in some examples may be between memory instances, while in other examples the delay is also introduced between bitcell arrays within a memory instance. Further examples may be configured to delay a power up signal, but to pass a power down signal more quickly through a series of sequentially-linked or daisy-chained memory instances. By staggering or delaying the power up times of interconnected or chained memory instances, inrush current when powering the memory instances on or resuming from an inactive state can be reduced.

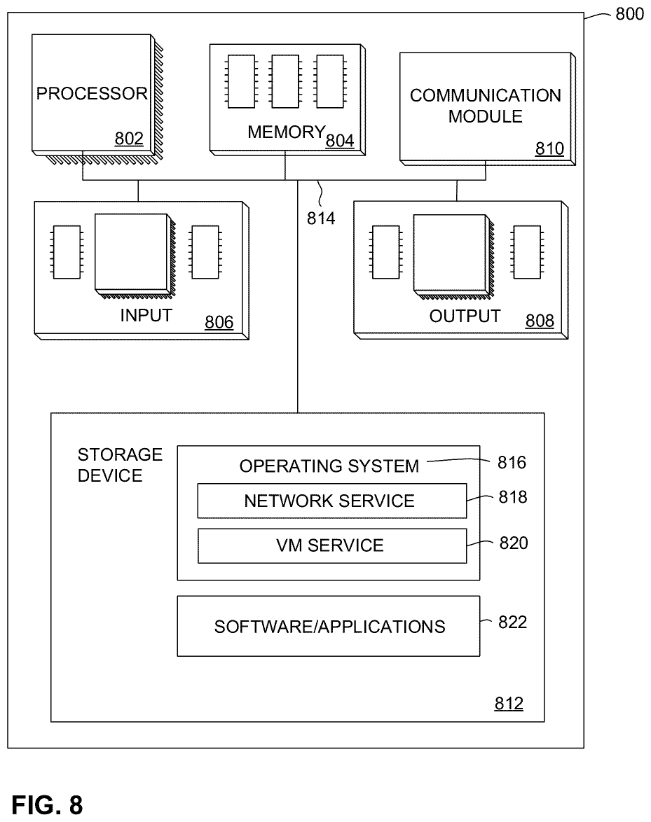

FIG. 8 shows a block diagram of a general-purpose computerized system, consistent with an example embodiment. FIG. 8 illustrates only one particular example of computing device 800, and other computing devices 800 may be used in other embodiments. Although computing device 800 is shown as a standalone computing device, computing device 800 may be any component or system that includes one or more processors or another suitable computing environment for executing software instructions in other examples, and need not include all of the elements shown here.

As shown in the specific example of FIG. 8, computing device 800 includes one or more processors 802, memory 804, one or more input devices 806, one or more output devices 808, one or more communication modules 810, and one or more storage devices 812.

Computing device 800, in one example, further includes an operating system 816 executable by computing device 800. The operating system includes in various examples services such as a network service 818 and a virtual machine service 820 such as a virtual server. One or more applications, such as application 822 are also stored on storage device 812, and are executable by computing device 800.

Each of components 802, 804, 806, 808, 810, and 812 may be interconnected (physically, communicatively, and/or operatively) for inter-component communications, such as via one or more communications channels 814. In some examples, communication channels 814 include a system bus, network connection, inter-processor communication network, or any other channel for communicating data. Applications such as software application 822 and operating system 816 may also communicate information with one another as well as with other components in computing device 800.

Processors 802, in one example, are configured to implement functionality and/or process instructions for execution within computing device 800. For example, processors 802 may be capable of processing instructions stored in storage device 812 or memory 804. Examples of processors 1202 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 812 may be configured to store information within computing device 800 during operation. Storage device 812, in some examples, is known as a computer-readable storage medium. In some examples, storage device 812 comprises temporary memory, meaning that a primary purpose of storage device 812 is not long-term storage. Storage device 812 in some examples is a volatile memory, meaning that storage device 812 does not maintain stored contents when computing device 800 is turned off. In other examples, data is loaded from storage device 812 into memory 804 during operation. Examples of volatile memories include random access memories (RAM), dynamic random access memories (DRAM), static random access memories (SRAM), and other forms of volatile memories known in the art. In some examples, storage device 812 is used to store program instructions for execution by processors 802. Storage device 812 and memory 804, in various examples, are used by software or applications running on computing device 800 such as software application 822 to temporarily store information during program execution.

Storage device 812, in some examples, includes one or more computer-readable storage media that may be configured to store larger amounts of information than volatile memory. Storage device 812 may further be configured for long-term storage of information. In some examples, storage devices 812 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 800, in some examples, also includes one or more communication modules 810. Computing device 800 in one example uses communication module 810 to communicate with external devices via one or more networks, such as one or more wireless networks. Communication module 810 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 800 uses communication module 810 to wirelessly communicate with an external device such as via a public network.

Computing device 800 also includes in one example one or more input devices 806. Input device 806, in some examples, is configured to receive input from a user through tactile, audio, or video input. Examples of input device 806 include a touchscreen display, a mouse, a keyboard, a voice responsive system, video camera, microphone or any other type of device for detecting input from a user.

One or more output devices 808 may also be included in computing device 800. Output device 808, in some examples, is configured to provide output to a user using tactile, audio, or video stimuli. Output device 808, in one example, includes a display, a sound card, a video graphics adapter card, or any other type of device for converting a signal into an appropriate form understandable to humans or machines. Additional examples of output device 808 include a speaker, a light-emitting diode (LED) display, a liquid crystal display (LCD or OLED), or any other type of device that can generate output to a user.

Computing device 800 may include operating system 816. Operating system 816, in some examples, controls the operation of components of computing device 800, and provides an interface from various applications such as software application 822 to components of computing device 800. For example, operating system 816, in one example, facilitates the communication of various applications such as software application 822 with processors 802, communication unit 810, storage device 812, input device 806, and output device 808. Applications such as application 822 may include program instructions and/or data that are executable by computing device 800. These and other program instructions or modules may include instructions that cause computing device 800 to perform one or more of the other operations and actions described in the examples presented herein.

Bitcell arrays, memory structures, memory instances, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, System Verilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses, or by any combination thereof or by any combination of features thereof:
Clause 1: A power multiplexer, comprising: an overdrive input operable to receive an indication of whether a first power voltage is higher than a second power voltage, the overdrive input driven at the second power voltage; a first switch coupled to receive the first power voltage and the overdrive input, the first switch configured to selectively provide the first power voltage to a first output based at least in part on the overdrive input; a level shifter operable to receive the overdrive input and to provide an inverted level-shifted overdrive input driven at the first power voltage; and a second switch coupled to receive the second power voltage and the inverted level-shifted overdrive input, the second switch configured to selectively provide the second power voltage to the first output based at least in part on inverted level-shifted overdrive input.
Clause 2: The power multiplexer of clause 1, wherein the power multiplexer lacks a direct current path between the first input voltage and the second input voltage.
Clause 3: The power multiplexer of any of clauses 1-2, wherein the first switch comprises a first PMOS transistor and the second switch comprises a second PMOS transistor.
Clause 4: The power multiplexer of any of clauses 1-3, wherein the first power voltage comprises a processor circuitry power voltage and the second power voltage comprises a memory cell power voltage.
Clause 5: The power multiplexer of any of clauses 1-4, further comprising one or more diodes coupled between an output of at least one of the first and second switches and the first or second power voltage
Clause 6: The power multiplexer of clause 5, wherein at least one of the one or more diodes comprise an NMOS transistor and a CMOS transistor coupled such that the drain of the NMOS transistor is coupled to the first or second power voltage, the gate of the NMOS transistor is coupled to the drain of the PMOS transistor, the source of the NMOS transistor coupled to the first output, and the gate and source of the PMOS transistor coupled to the source of the NMOS transistor.
Clause 7: The power multiplexer of any of clauses 1-6, further comprising a delay circuit coupling at least one of the first and second switches and the overdrive input.
Clause 8: The power multiplexer of any of clauses 1-7, further comprising: a first level shifter coupled to receive the indication of whether the first power voltage is higher than the second power voltage, the second power voltage, and the first output; a second level shifter coupled to receive a power down signal or a retention mode power signal and the second power voltage; a first NAND gate operable to receive an output from the first level shifter, an output from the second level shifter; a second NAND gate operable to receive an output from the first NAND gate and the output from the second level shifter; a first rising edge delay circuit operable to receive the output from the first NAND gate; a second rising edge delay circuit operable to receive an output from the second NAND gate; a first PMOS output transistor having a drain coupled to the second power voltage, a gate coupled to an output of the first rising edge delay circuit, and a source coupled to a bitcell output; and a second PMOS output transistor having a drain coupled to the first power voltage, a gate coupled to an output of the second rising edge delay circuit, and a source coupled to the bitcell output.
Clause 9: The power multiplexer of clause 8, wherein first and second NAND gates are powered by the first output.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. A memory instance, comprising:
a first memory comprising a first bitcell array and first peripheral circuitry;
a bitcell array power supply providing a first bitcell array power supply fixed voltage;
a first peripheral logic power supply providing a first peripheral logic power supply variable voltage to first peripheral circuitry; and
a first power multiplexer operable to provide a higher of the first bitcell array power supply fixed voltage and the first peripheral logic power supply variable voltage to the first bitcell array.

2. The memory instance of claim 1, further comprising:
a second memory comprising a second bitcell array and second peripheral circuitry, the bitcell array power supply providing a second bitcell array power supply fixed voltage;
a second peripheral logic power supply providing a second peripheral logic power supply variable voltage to the second peripheral circuitry, the second peripheral logic power supply variable voltage to be different from the first peripheral logic power supply variable voltage; and
a second power multiplexer operable to provide a higher of the second bitcell array power supply fixed voltage and the second peripheral logic power supply variable voltage to the second bitcell array.

3. The memory instance of claim 2, wherein the first memory is associated with a first processor core in a computer system operating at a first performance level and the second memory is associated with a second processor core in the computer system operating at a second performance level.

4. The memory instance of claim 3, further comprising multiple memories and associated processors at the first performance level, multiple memories and associated processors at the second performance level, or a combination thereof.

5. The memory instance of claim 2, further comprising at least one additional memory comprising an additional bitcell array, additional peripheral circuitry, and an additional power multiplexer; the additional peripheral circuitry coupled to one of the first peripheral logic power supply and the second peripheral logic power supply, the additional power multiplexer operable to provide a higher of the bitcell array power supply fixed voltage, and the one of the first peripheral logic power supply and the second peripheral logic power supply coupled to the additional peripheral circuitry to the additional bitcell array.

6. The memory instance of claim 1, wherein the first power multiplexer comprises a digital circuit configured to avoid a direct current path between the bitcell array power supply and the first peripheral logic power supply.

7. The memory instance of claim 2, wherein the first power multiplexer comprises a digital circuit configured to avoid a direct current path between the bitcell array power supply and the first peripheral logic power supply and the second power multiplexer comprises a digital circuit configured to avoid a direct current path between the bitcell array power supply and the second peripheral logic power supply.

8. The memory instance of claim 1, wherein the first power multiplexer further comprises a first overdrive enable input operable to receive an indication of whether the first peripheral logic power supply is at a voltage higher than the first bitcell array power supply fixed voltage, the received first overdrive enable input operable to cause the first power multiplexer to provide the higher of the first bitcell array power supply fixed voltage and the first peripheral logic power supply variable voltage to the first bitcell array.

9. The memory instance of claim 2, wherein the first power multiplexer further comprises a first overdrive enable input operable to receive an indication of whether the first peripheral logic power supply variable voltage is at a voltage higher than the first bitcell array power supply fixed voltage and the second power multiplexer further comprises a second overdrive enable input operable to receive an indication of whether the second peripheral logic power supply variable voltage is at a voltage higher than the second bitcell array power supply fixed voltage.

10. A method of providing power to a memory, comprising:
providing a bitcell array power signal at a bitcell array power signal fixed voltage to a first power multiplexer;
providing a first peripheral logic power signal at a first peripheral logic power supply variable voltage to a first peripheral circuitry of a first memory and to the first power multiplexer; and
providing, via the first power multiplexer, a higher of the bitcell array power signal fixed voltage and the first peripheral logic power supply variable voltage to a first bitcell array of the first memory.

11. The method of claim 10, further comprising:
providing a second peripheral logic power signal at a second peripheral logic power supply variable voltage to a second peripheral circuitry of a second memory and to a second power multiplexer; and
providing, via the second power multiplexer, a higher of the bitcell array power signal fixed voltage and the second peripheral logic power supply variable voltage to a second bitcell array of the second memory.

12. The method of claim 11, wherein the first memory is associated with a first processor core in a computer system operating at a first performance level and the second memory is associated with a second processor core in the computer system operating at a second performance level.

13. The method of claim 12, further comprising providing multiplexed power to multiple memories and associated processors at first performance level, multiple memories and associated processors at second performance level, or a combination thereof.

14. The method of claim 11, further comprising:
providing a higher of the bitcell array power signal fixed voltage and a selected one of the first peripheral logic power signal and the second peripheral logic power signal to at least one bitcell array of at least one additional memory, a peripheral circuitry of the at least one additional memory coupled to the selected one of the first peripheral logic power signal and the second peripheral logic power signal.

15. The method of claim 10, wherein the first power multiplexer comprises a digital circuit configured to avoid a direct current path between the bitcell array power signal and the first peripheral logic power signal.

16. The method of claim 11, wherein the first power multiplexer comprises a digital circuit configured to avoid a direct current path between the bitcell array power signal and the first peripheral logic power signal and the second power multiplexer comprises a digital circuit configured to avoid a direct current path between the bitcell array power signal and the second peripheral logic power signal.

17. The method of claim 10, further comprising receiving a first overdrive enable input in the first power multiplexer indicating whether the first peripheral logic power signal is at a voltage higher than the bitcell array power signal fixed voltage.

18. The method of claim 11, further comprising receiving an indication of whether the first peripheral logic power supply variable voltage is at a voltage higher than the bitcell array power signal fixed voltage in the first power multiplexer, and receiving an indication of whether the second peripheral logic power supply variable voltage is at a voltage higher than the bitcell array power signal fixed voltage in the second power multiplexer.

19. A power multiplexer, comprising:
an overdrive input operable to receive an indication of whether a first power voltage is higher than a second power voltage, the overdrive input driven at the second power voltage;
a first switch coupled to receive the first power voltage and the overdrive input, the first switch configured to selectively provide the first power voltage to an output based at least in part on the overdrive input;
a level shifter operable to receive the overdrive input and to provide an inverted level-shifted overdrive input driven at the first power voltage; and
a second switch coupled to receive the second power voltage and the inverted level-shifted overdrive input, the second switch configured to selectively provide the second power voltage to the output based at least in part on inverted level-shifted overdrive input.

20. The power multiplexer of claim 19, wherein the power multiplexer lacks a direct current path between the first power voltage and the second power voltage.
